(19) United States
(12) Patent Application Publication
(10) Pub. No.: US 2024/0385014 A1
(43) Pub. Date: Nov. 21, 2024

(54) MULTIPLE INPUT DC METER

(71) Applicant: PACIFIC GAS AND ELECTRIC COMPANY, Oakland, CA (US)

(72) Inventors: Earle Davis, Walnut Creek, CA (US); Alan Jones, Berkeley, CA (US); Mei Chen, San Francisco, CA (US); Bonnie Tong, San Francisco, CA (US); Alex Yan, Berkeley, CA (US); Quoc Hoang, Walnut Creek, CA (US)

(21) Appl. No.: 18/785,530

(22) Filed: Jul. 26, 2024

Related U.S. Application Data
(62) Division of application No. 17/590,522, filed on Feb. 1, 2022.
(60) Provisional application No. 63/145,096, filed on Feb. 3, 2021.

(51) Int. Cl. G01D 4/00; G01R 19/00; G01R 31/42; H04B 3/54

(52) U.S. Cl. CPC G01D 4/002; G01R 19/0007; G01R 31/42; H04B 3/54; H04B 2203/5433

(57) ABSTRACT

Some embodiments describe a DC meter system that can be placed in-line between a power source and an electrical load. In some embodiments, the DC meter system includes a DC meter that has multiple inputs for receiving electricity from multiple power sources. In some embodiments, the DC meter has one or more outputs, each capable of delivering electricity to a different electrical load. In some embodiments, the DC meter can combine electricity from two or more of the multiple inputs into one of the outputs. In some embodiments, the DC meter has a controller that can enable a user to deliver electricity from a particular input to a particular output. In some embodiments, the DC meter is configured to enable transition of electricity between an input and an output in a bi-directional manner. In some embodiments, the DC meter can record an amount of electricity transmitted in either direction.

### CROSS-REFERENCE TO RELATED APPLICATIONS

This application is a Divisional of U.S. patent application Ser. No. 17/590,522, filed Feb. 1, 2022, entitled “MULTIPLE INPUT DC METER,” which claims the benefit of and priority to U.S. Provisional Patent Application No. 63/145,096, filed Feb. 3, 2021, the entire contents of which are hereby incorporated by reference herein.

### BACKGROUND

There has been a long felt, but unmet need for a system capable of accurately tracking and billing DC power sources for utility companies. Without such technology available in today's market, utility companies must estimate and/or flat bill customers' DC watt hour usage. In addition, the market lacks a commercially available solution to record both AC and DC power usage using a single system.

Therefore, there is a need for unified system capable of measuring and monitoring multiple inputs of AC and DC power.

### SUMMARY

In some embodiments, the system includes a Multiple Input DC watt hour meter (“DC meter”). In some embodiments, the DC meter is an intelligent, wirelessly communicable and wide auto-ranging meter. In some embodiments, the DC meter includes an operating voltage range of 12-600 VDC. In some embodiments, the DC meter is configured to measure energy consumption and/or generation from direct current (“DC”) power sources. In some embodiments, example DC power sources include photovoltaic sources, battery storage, electric vehicles (EV), DC chargers, and/or rectifiers supplied with alternating current (AC). In some embodiments, the system is configured to accept, measure and/or control electrical energy flow. In some embodiments, the system is configured to accept, measure and/or control electrical energy flow bi-directionally for each of one or more DC inputs independently. In some embodiments, the system is configured to control connections between one or more DC inputs. In some embodiments, controlling connections includes turning on or off one or more internal disconnect switches.

In some embodiments, the system is configured to measure and/or record real-time DC data (e.g., energy, watt, voltage and/or current) from one or more DC inputs received by the system independently. In some embodiments, the system is configured to transmit the measured DC data to a central metering management system and/or one or more computers for billing by a provider. In some embodiments, the provider is a utility company. In some embodiments, the provider is a property owner providing DC power to one or more customers and/or the utility company.

In some embodiments, the system includes a revenue grade DC watt hour meter with a small footprint (e.g., length≤3″×width≤3″×height≤3″) configured to accurately measure residential and commercial loads, allows installation in confined space, and/or reduce material and installation costs. In some embodiments, the DC meter is configured to enable the formation and electrical usage tracking of a micro-grid (e.g., residential and/or commercial customers). In some embodiments, an example micro-grid comprises energy from a variety of sources that include both commercial utility companies (e.g., industrial power plants) and private property (e.g., vehicle or other batteries and charging systems, solar panels, windmills, etc.).

In some embodiments, the system includes a backup transfer power meter (BPTM) meter configured to couple to one or more backup power sources (e.g., vehicle or other batteries and charging systems, solar panels, windmills, etc.). In some embodiments, the system enables one or more backup power sources to be directly connected to the DC meter. In some embodiments, a separate electrical panel is not required between the any of the one or more backup power sources and the DC meter. In some embodiments, circuitry within the DC meter housing is configured to enable one or more of: multiple parallel generation, WiFi connectivity, transfer switch selection and control, generating one or more user interfaces (UI or GUI), communication connections, one or more (universal) amperage adaptor plugs, and next generation meter (NGM) core integration.

In some embodiments, DC meter multiple parallel generation circuitry enables the one or more electrical loads to draw power from the one or more DC backup power sources simultaneously. In some embodiments, the BPTM includes phase monitoring circuitry configured to provide protection for electrical devices by monitoring and/or providing notification if any phase is reversed, missing, or out of balance. In some embodiments, the DC meter comprises WiFi connectivity that enables wireless communications to control and/or receive alerts from the system. In some embodiments, the DC meter comprises a DC transfer switch selection and control enables a user to: select which of the one or more backup power sources are enabled automatically, to choose a sequence for bringing backup power sources online, and/or run two or more backup power sources in parallel. In some embodiments, the DC meter comprises a user interface enables a user to visually and/or audibly receive information from a meter and/or control one or more meters (BPTM and/or DC meter) functions. In some embodiments, communication connections enable data transmission to one or more wired and/or wireless communication devices. In some embodiments, one or more universal amperage adaptor plugs enables a backup power source supply to be converted to the correct amperage/voltage for a particular load.

In some embodiments, the DC Meter is configured to communicate with the Backup Power Transfer meter over a wired and/or wireless network. In some embodiments, the system includes a rectifier. In some embodiments, the rectifier is configured to convert DC electrical input from a plurality of DC power sources to AC power. In some embodiments, each DC power source includes a single DC power meter configured to record and/or transmit DC electrical data. In some embodiments, the DC electrical data is transmitted to the BPTM. In some embodiments, the BPTM is configured to record and/or transmit the data received from one or more DC meters to one or more computers.

In some embodiments, the BPTM is configured to receive AC power supplied by the rectifier as a backup power source. In some embodiments, the BPTM is configured to record and/or transmit the AC rectifier data received from the rectifier to one or more computers. In some embodiments, the system is configured to monitor the rectifier (e.g., for efficiency and/or malfunction) by measuring electrical energy both before (using a DC meter) and after (using an AC BPTM) the rectifier.

In some embodiments, the rectifier is configured to receive DC power from a plurality of DC power sources. Advantageously, in some embodiments, a single DC meter is configured to receive and control the connection between multiple DC power sources and output a single DC supply from the DC power meter. In some embodiments, this multiple DC input and single DC output saves material and installation cost while also providing a method of recording and/or transmitting the draining and/or charging of multiple DC power sources. In some embodiments, the system is configured to enable the BPTM to control the DC meter. In some embodiments, the system is configured to enable the BPTM to control which of the plurality of DC power sources the DC meter supplies to the rectifier upon a loss of utility power. In some embodiments, the system is configured to enable the DC meter to control which of the plurality of backup power sources the BTPM meter supplies to a load. In some embodiments, one or more of the system controls are integrated into one or more of the BTPM and the DC meter.

Some embodiments are directed to a direct current (DC) metering system comprising at least one a DC meter. In some embodiments, the DC meter is configured to be integrated into an electrical transmission line. In some embodiments, the DC meter is configured to measure and/or record a transfer of electricity from a DC power source to an electrical load along the electrical transmission line. In some embodiments, the DC meter is configured to measure and/or control the transfer of electricity bi-directionally, where bi-directional control includes the transfer of electricity to and/or from the DC power source.

In some embodiments, DC power sources include photovoltaic sources, battery storage, electric vehicles (EV), DC chargers, and/or rectifiers supplied with alternating current (AC). In some embodiments, the DC meter is configured to transmit measured DC data to one or more computers. In some embodiments, the DC meter is configured to transmit the measured DC data to one or more computers over a wireless network. In some embodiments, the DC meter comprises WiFi connectivity that enables wireless communications to and/or from the DC meter. In some embodiments, the wireless communications include control and/or programming one or more functions of the DC meter. In some embodiments, the DC meter comprises a user interface configured to enable a user to visually and/or audibly receive information from a meter and/or control one or more meters functions. In some embodiments, the DC meter comprises a housing, and the user interface is located on the housing.

In some embodiments, the DC meter is configured to receive and/or control an electrical input from two or more DC power sources. In some embodiments, the DC meter comprises multiple parallel generation circuitry. In some embodiments, the multiple parallel generation circuitry enables the DC metering to simultaneously draw power from the two or more DC power sources.

In some embodiments, the DC meter comprises a controller that enables a user to control one or more DC meter functions. In some embodiments, the one or more DC meter functions include one or more of: selecting which of the two or more DC power sources to enable automatically, selecting a sequence for bringing the two or more DC power sources online, and configuring the DC meter to transmit electricity from each of the two or more DC power sources in parallel.

In some embodiments, the DC meter includes two or more DC inputs. In some embodiments, the DC meter includes one or more DC outputs. In some embodiments, the DC meter is configured to transmit electricity from each of the two or more DC inputs to the one or more DC outputs. In some embodiments, the DC meter includes two or more channels. In some embodiments, the two or more channels each comprise an electricity transmission connection between at least one of the two or more DC inputs and at least one of the one or more DC outputs. In some embodiments, the DC meter is configured to measure and record an amount of electricity flowing through each of the two or more channels.

In some embodiments, the DC meter includes at least a first DC input and a second DC input each configured to receive the electricity from a first DC power source and a second DC power source, respectively. In some embodiments, the DC meter includes at least a first DC output and a second DC output each configured to send the electricity to a first electrical load and a second electrical load, respectively. In some embodiments, the controller is configured to enable a user to select to send electricity from the first DC power source or second DC power source to one or more of the first electrical load, the second electrical load, and both the first electrical load and the second electrical load. In some embodiments, the controller is configured to enable a user to combine electricity from the first DC power source with electricity from the second DC power source before sending the combined electricity to one or more of the first electrical load, the second electrical load, and both the first electrical load and the second electrical load.

In some embodiments, the DC meter is configured to measure, record, and/or transmit an amount of electricity flowing through each of the first DC input, the second DC input, the first DC output, and second DC output. In some embodiments, the DC meter comprises a housing comprising a user interface configured to enable a user to visually and/or audibly receive information from the DC meter and/or control one or more DC meter functions.

### BRIEF DESCRIPTION OF THE DRAWINGS

FIG. 1 shows an example single input/output DC Meter according to some embodiments.

FIG. 2 illustrates a multiple input/output DC Meter according to some embodiments.

FIG. 3 depicts a DC Meter block diagram according to some embodiments.

FIG. 4 is a simplified wiring diagram illustrating the system metering directly from a utility owned rectifier.

FIG. 5 illustrates the system employed in a micro-grid according to some embodiments.

FIG. 6 illustrates the system employing both a BPTM and a DC meter according to some embodiments.

FIG. 7 depicts a portion of the system showing a BPTM that includes a User Disconnect Module (UDM) 200 according to some embodiments.

FIGS. 8-17 are detailed schematics representing some embodiments of the DC meter.

FIG. 18 illustrates a computer system 410 enabling or comprising the systems and methods in accordance with some embodiments of the system.

### DETAILED DESCRIPTION

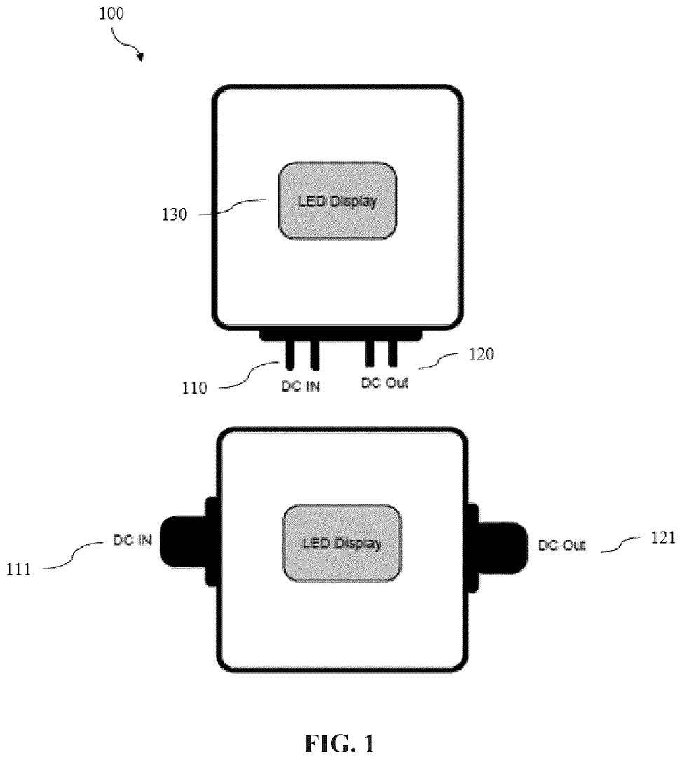

FIG. 1 shows an example single input/output DC Meter 100 according to some embodiments. In some embodiments, the DC meter includes a single conventional DC input 110, 111 and a single conventional DC output 120, 121. In some embodiments, the DC meter 100 includes a user interface (UI) 130 configured to enable a user to control one or more DC meter controls. In some embodiments, the UI includes a display (e.g., a conventional LED display). In some embodiments, the display is a touchscreen. In some embodiments, the display is configured to show one or more system settings and/or power conditions.

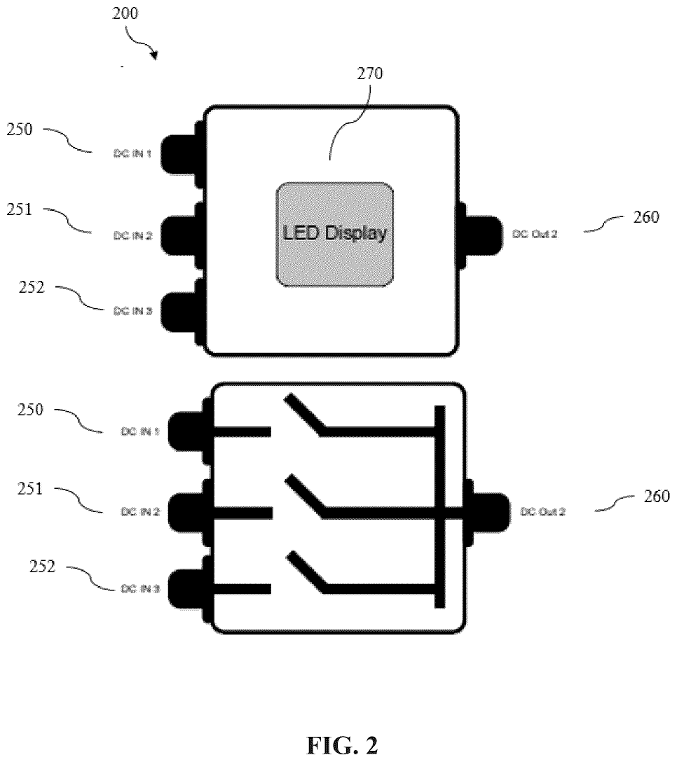

FIG. 2 illustrates a multiple input/output DC Meter 200 according to some embodiments. In some embodiments, the DC meter includes a multiple conventional DC inputs 250, 251, 252. In some embodiments, the DC meter includes a single conventional DC output 260. Advantageously, since the DC meter is bi-directional, the same DC meter acts as a DC meter with multiple conventional DC outputs (i.e., 250, 251, 252) and a single conventional DC input (i.e., 260) according to some embodiments. In some embodiments, an example where this arrangement is useful is a construction site where multiple EV vehicles are powering a rectifier that runs site equipment. In this case, according to some embodiments, the meter is configured to measure power consumption and manage which vehicle power is drawn from. In some embodiments, power is drawn from multiple vehicles in parallel. In some embodiments, the system is configured to draw power from one or more vehicles until the each EV's battery level reaches a pre-determined limit. Conversely, since the DC meter is bi-directional, the DC power meter is configured to measure, control, and transmit power usage when a power source (e.g., a generator supplying DC power through a rectifier) at the jobsite charges the one or more EVs according to some embodiments.

In some embodiments, the DC meter includes multiple conventional DC inputs and outputs, where each input-output is a channel. In some embodiments, a single DC meter with multiple channels is configured to measure, record, and/or transmit DC power data for each channel. In some embodiments, this allows a single DC meter to act as a plurality of DC meters. In some embodiments, the DC meter is configured to converge two or more channel inputs into a single channel output. In some embodiments, this enables a DC meter with multiple channels to act as a DC meter with multiple inputs and a single output (or vise versa) as described above.

In some embodiments, the DC meter 200 includes a user interface (UI) 270 configured to enable a user to control one or more DC meter controls. In some embodiments, the UI includes a display (e.g., a conventional LED display). In some embodiments, the display is a touchscreen. In some embodiments, the display is configured to show one or more system settings and/or power conditions.

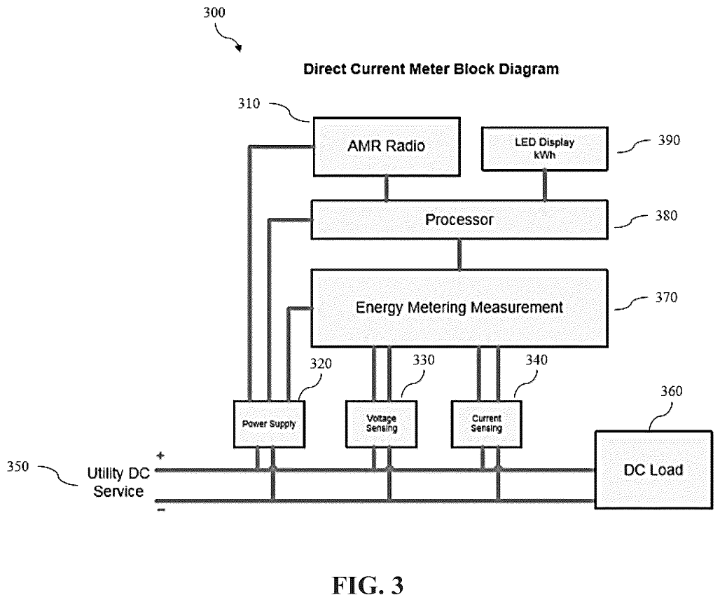

FIG. 3 depicts a DC meter block diagram 300 according to some embodiments. In some embodiments, the DC meter includes conventional Automatic Meter Reading (AMR) technology including an AME radio 310. In some embodiments, the DC meter includes a power supply module 320 that provides power to the DC meter components. In some embodiments, the DC meter includes a voltage sensing module 330 and/or a current sensing module 340 configured to measure voltage and/or current supplied from a power source 350 to a DC load 360. In some embodiments, the voltage sensing module 330 and/or the current sensing module 340 is configured to transmit the measurements to the energy metering measurement module 370. In some embodiments, the energy metering measurement module 370, the AMR radio 310, and/or LED display 390 are connected to one or more processors 380 executing control instructions stored on one or more non-transitory computer readable media.

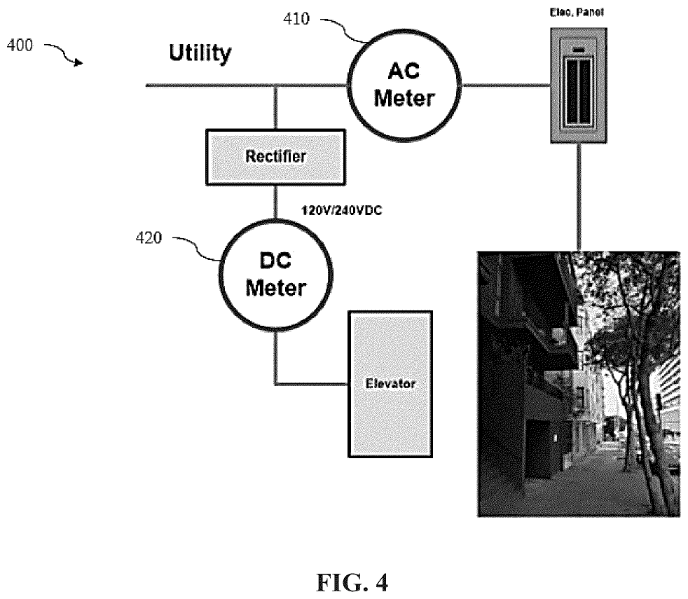

FIG. 4 is a simplified wiring diagram 400 illustrating the system metering directly from a utility owned rectifier. In some embodiments, the AC meter 410 (e.g., a BPTM) and the DC meter 420 operate independently.

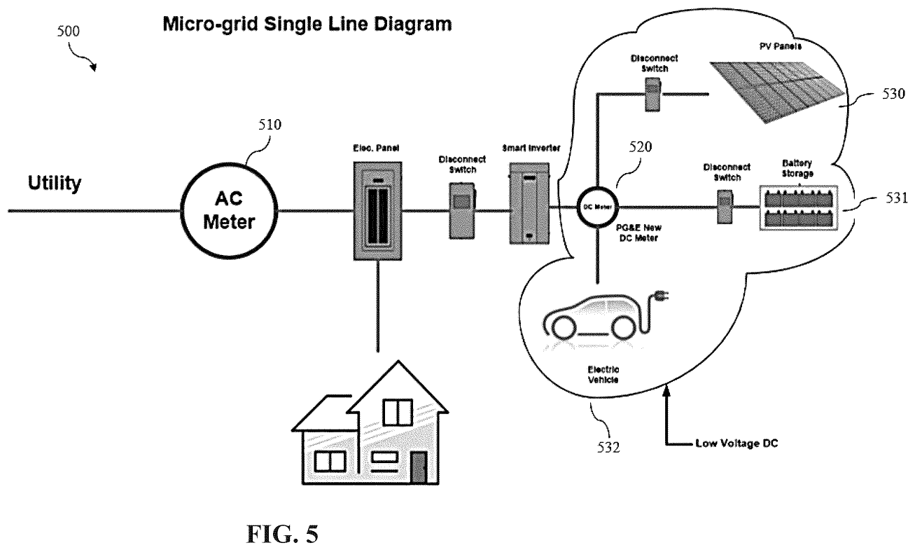

FIG. 5 illustrates the system employed in a micro-grid 500 according to some embodiments. In some embodiments, the DC meter 520 is configured to control and meter the supply from one or more backup power sources 530-532. In some embodiments, the AC meter 510 (e.g., a BPTM) and the DC meter 520 operate independently.

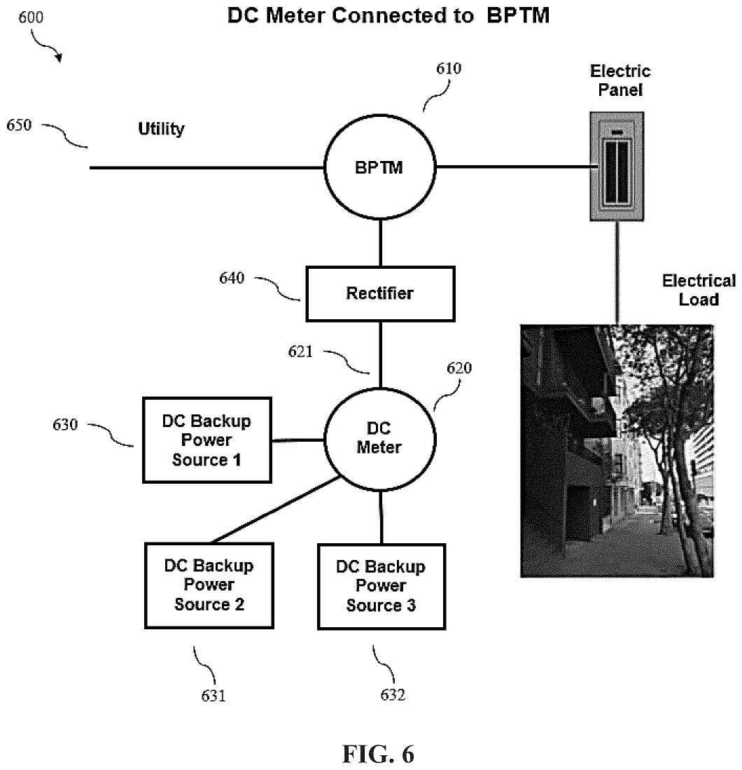

FIG. 6 illustrates the system 600 employing both a BPTM 610 and a DC meter 620 according to some embodiments. In some embodiments, the system 600 is configured to measure, control, store, and/or transmit DC power and/or DC power data collected from each DC backup power source 630-632. In some embodiments, the DC meter 620 is configured to transmit the collective DC power from each DC backup power source 630-632 through a single DC outlet 621 to a rectifier 640. In some embodiments, the BPTM 610 is configured to measure, control, store, and/or transmit AC power received from the rectifier 640. In some embodiments, the BPTM is configured to select whether to receive power from a utility power source 650 or the rectifier 640.

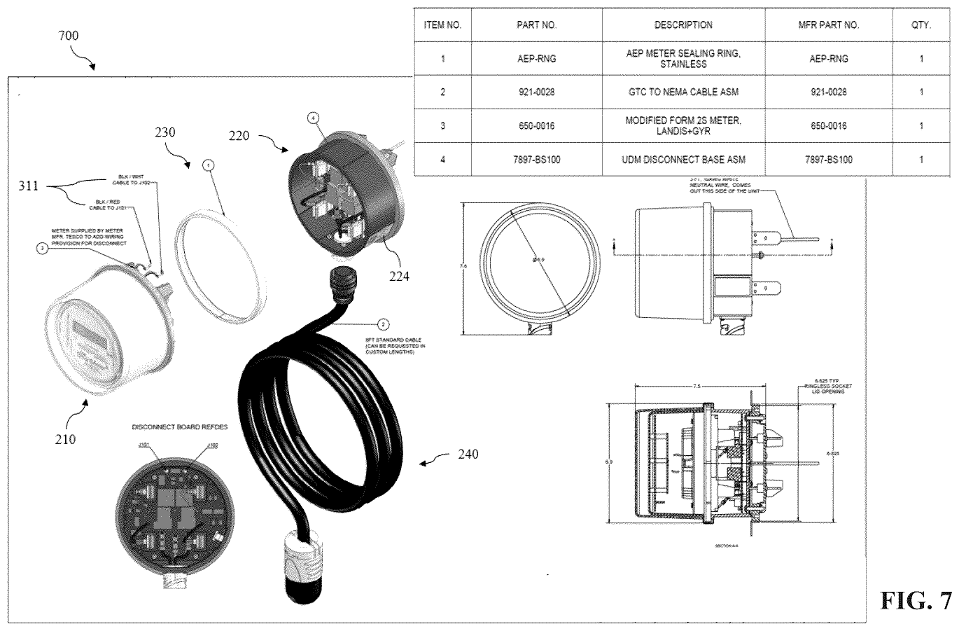

FIG. 7 depicts a portion of the BPTM that includes a user disconnect module (UDM) 200 according to some embodiments. In some embodiments, the UDM 200 includes two main assemblies: the meter 210 and the smart socket adaptor 220 (also referred to as a UDM disconnect base or housing). In some embodiments, the meter 210 includes one or more of a network card and internal disconnect switch. In some embodiments, the meter 210 is configured such that the electrical connection between the meter's Printed Circuit Board (PCB) and a disconnect relay motor is separated. In some embodiments, the meter 210 includes a Focus AXR-SD 2S electric meter with a Silver Spring Network card and internal disconnect switch, for example. In some embodiments, connections for the meter's PCB and disconnect relay motor are configured to be individually wired back to the smart socket adaptor 220.

In some embodiments, the smart socket adaptor 220 includes one or more of three components: the housing 221, a PCB 222 (e.g., provided by TESCO) mounted in the housing 221, the generator connector 223, and/or a pushbutton panel 224. In some embodiments, the PCB 222 is configured to control a disconnect switch motor in the meter 210. In some embodiments, the system uses the meter 210's disconnect relay contacts to isolate utility power from an electrical load (e.g., one or more electrical devices coupled to a panel located in a house). In some embodiments, high current relays isolate the backup power source (e.g., generator) from the electrical load. In some embodiments, the PCB 222 includes one or more voltage sensors configured to detect the presence of utility and backup power source throughout the module.

In some embodiments, the UDM 200 provides a safe, easy to use way for a user to connect one or more backup power sources to electrical loads. For example, in some embodiments, the UDM is configured to couple to one or more VAC, 30 Amp generators.

In some embodiments, the system includes one or more backup power connectors extending from the system housing configured to couple to one or more backup power sources. In some embodiments, one or more backup power sources are coupled using one or more interconnect cables 240 (see FIGS. 2 and 4). In some embodiments, the cable has connectors on both ends: a 3-pole high current connector on one side and a conventional connector (e.g., L14-30P) on the other side.

In some embodiments, to couple the meter 210 to the socket adaptor 220, a user first identifies the two wire pairs 311 extending from the back of the meter 210 (see FIG. 3). In some embodiments, the RED/BLK connector (FIG. 3) is configured to be plugged into J101 connector on the TESCO PCB (FIG. 5). In some embodiments, the RED/WHT (FIG. 3) is configured to be plugged into J102 (FIG. 5) connector on the PCB 222. In some embodiments, the meter 210 is pushed into the adaptor 220 such that the meter stabs and the adaptor blades on the two wire pairs 311 are fully engaged. In some embodiments, the meter ring 230 (see FIG. 3) is then installed to secure the connection between the two components.

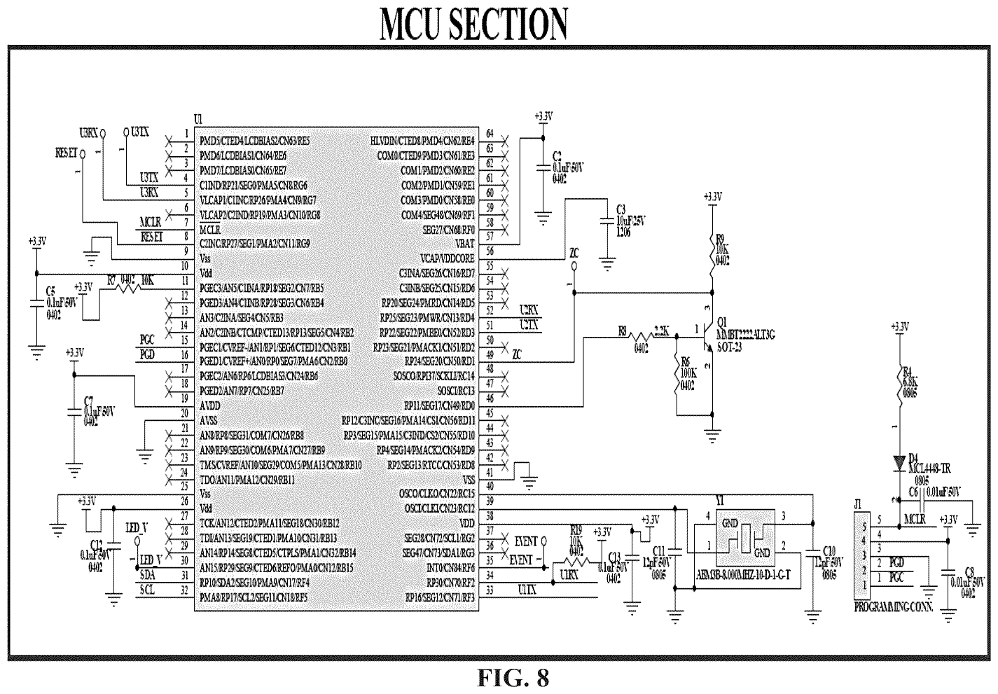

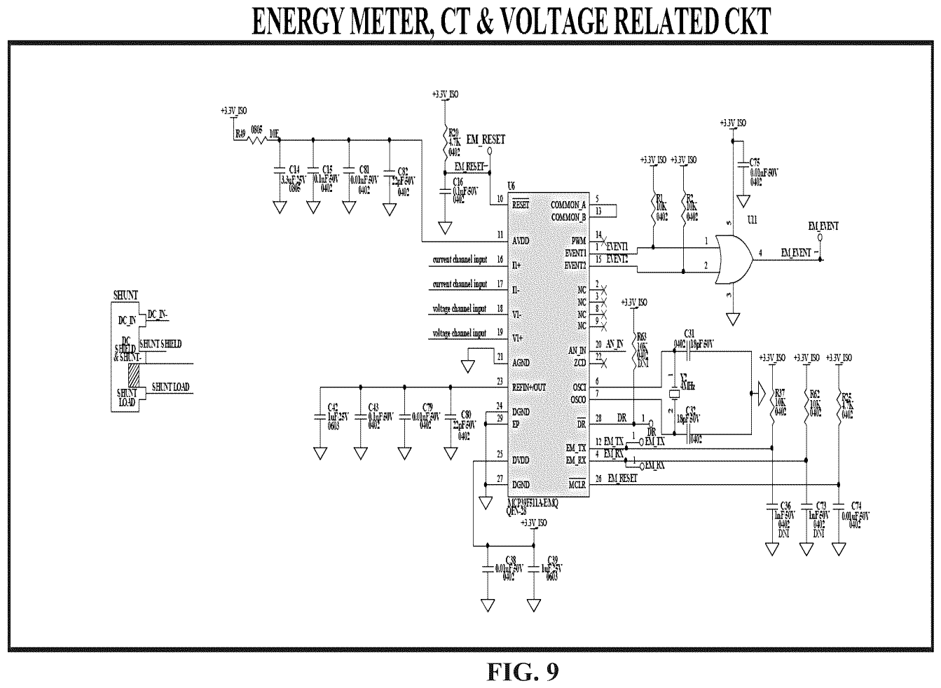

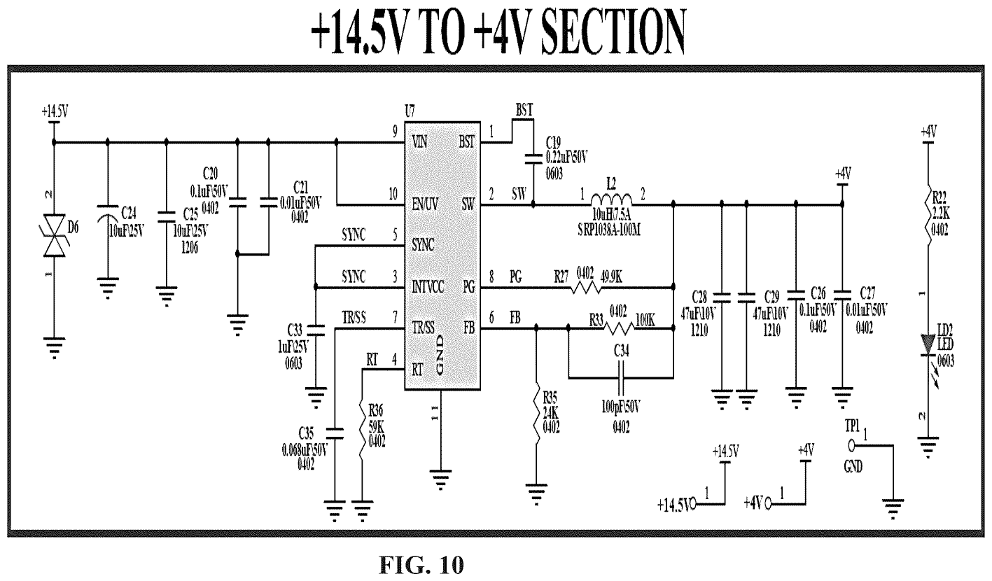

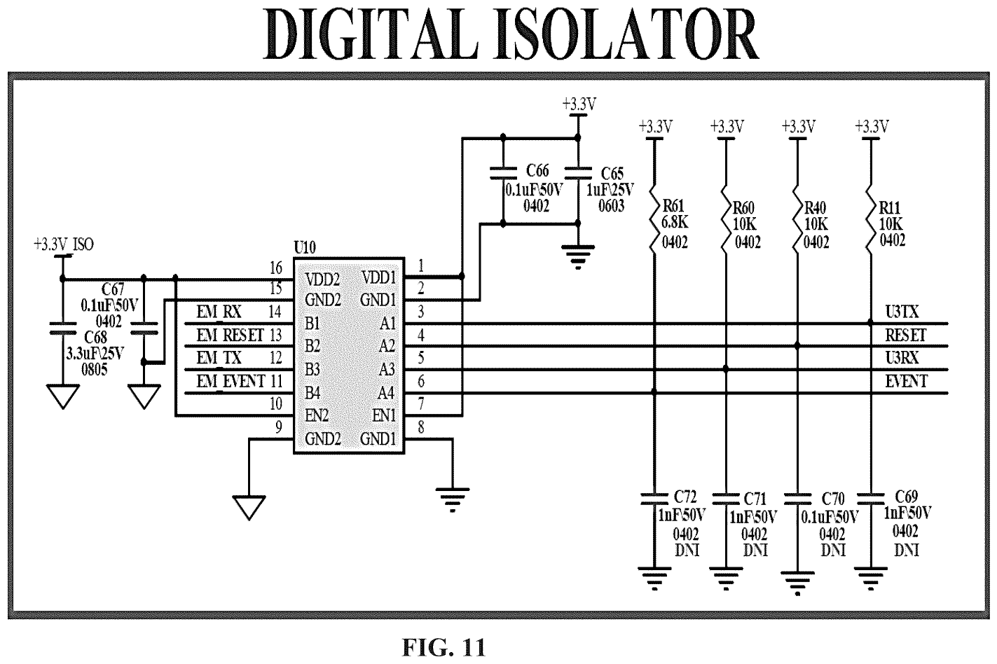

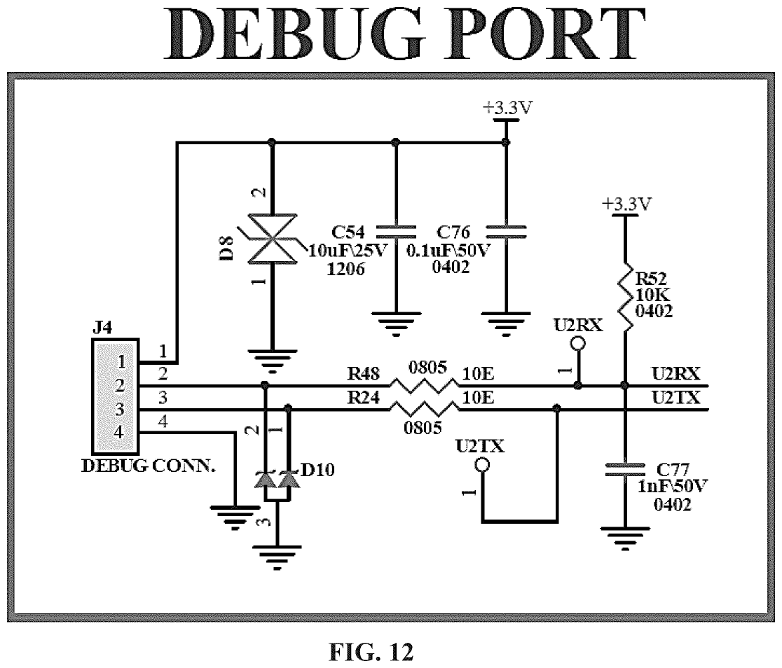

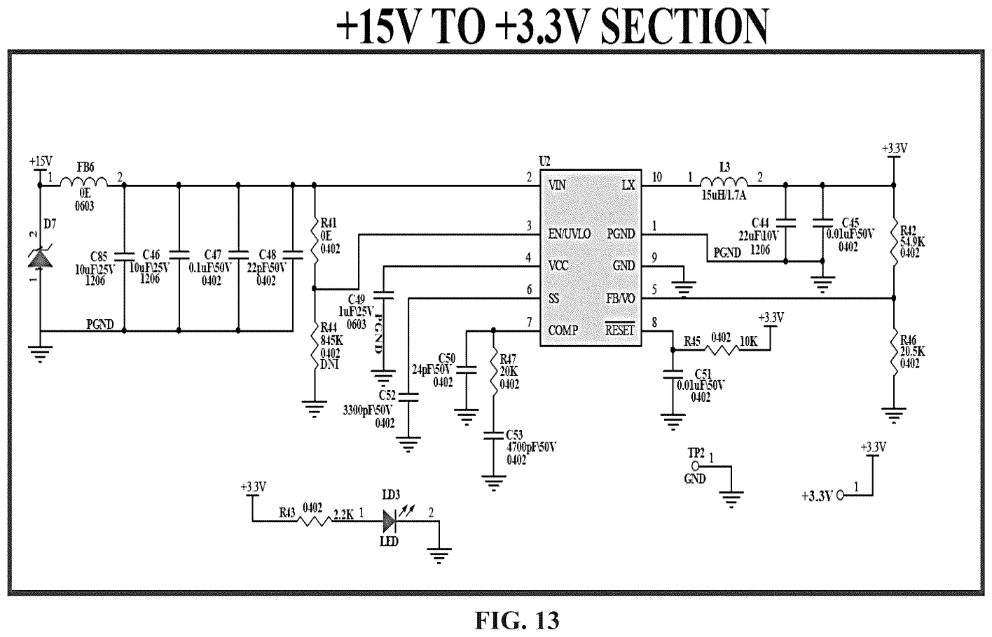

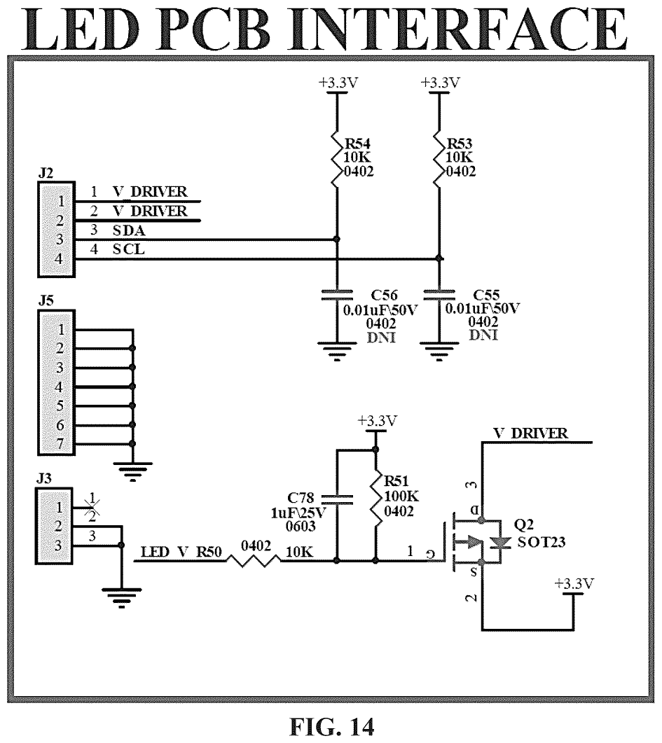

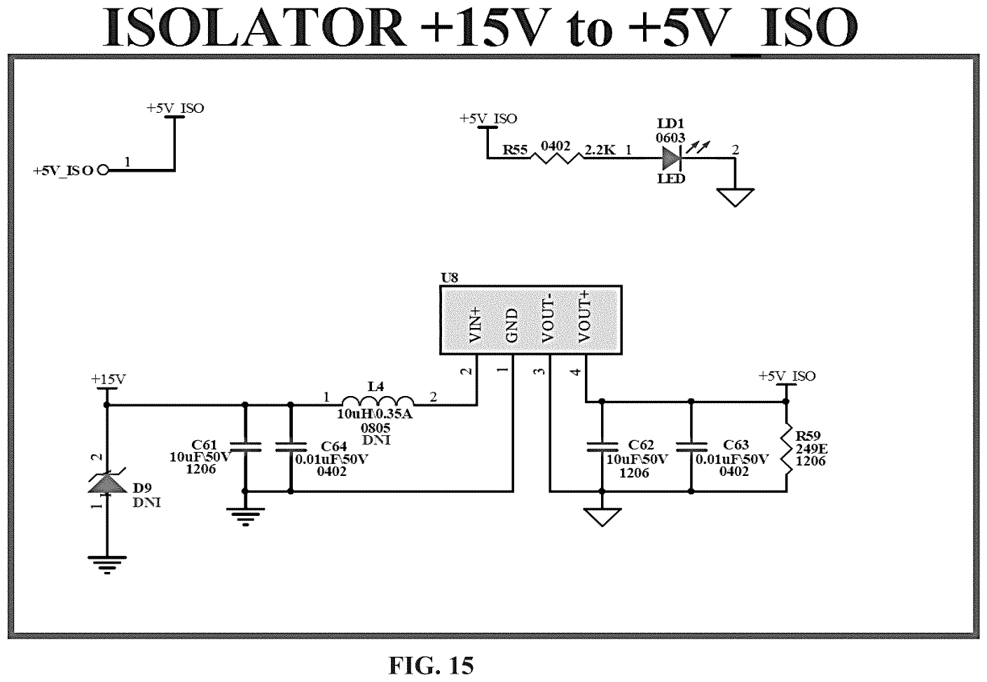

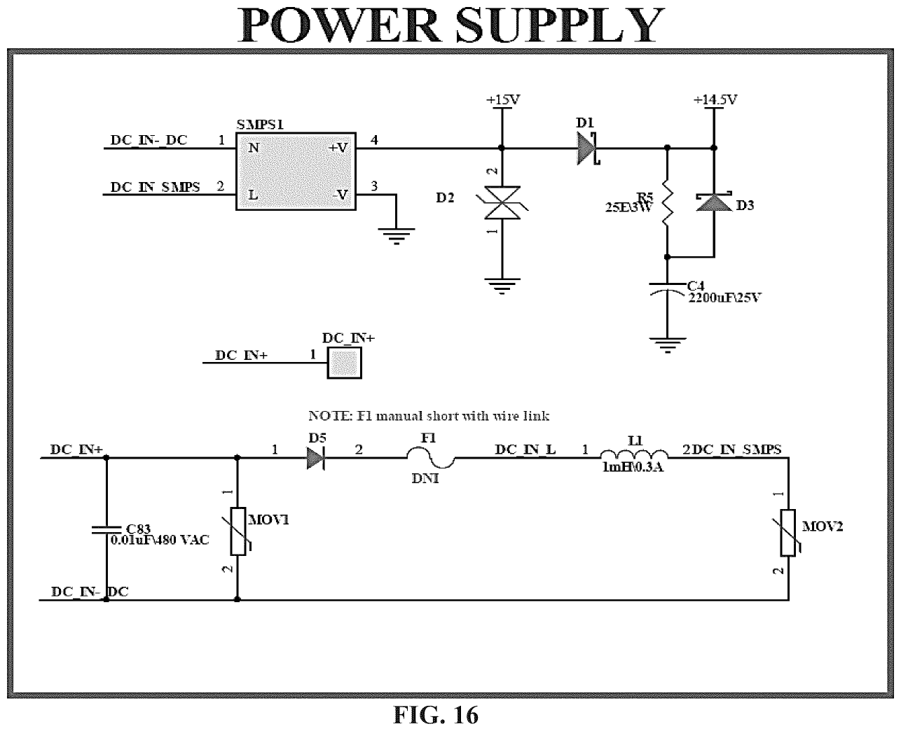

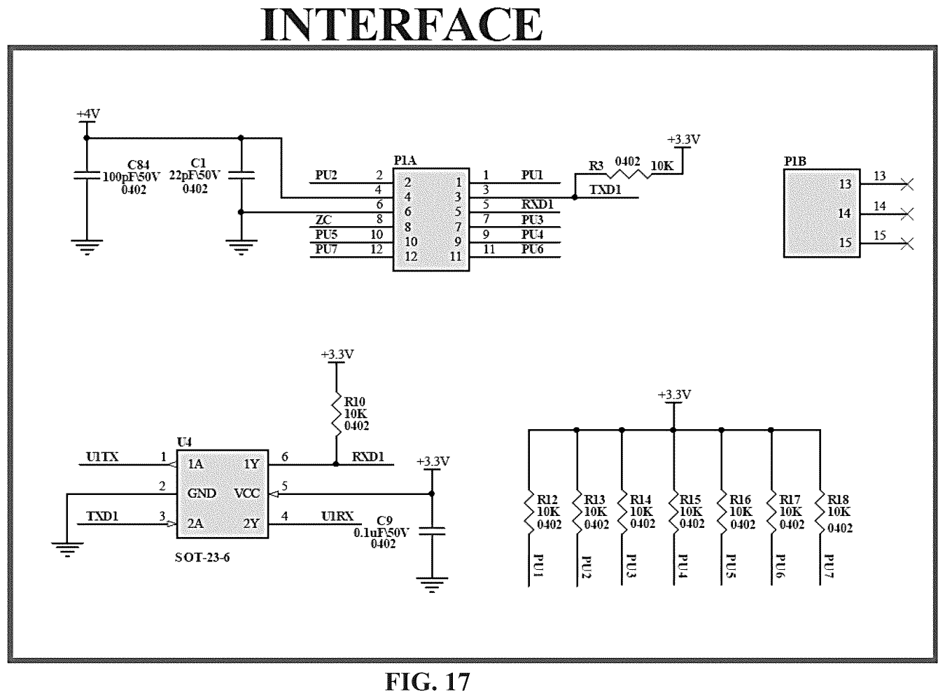

FIGS. 8-17 are detailed schematics representing some embodiments of the DC meter.

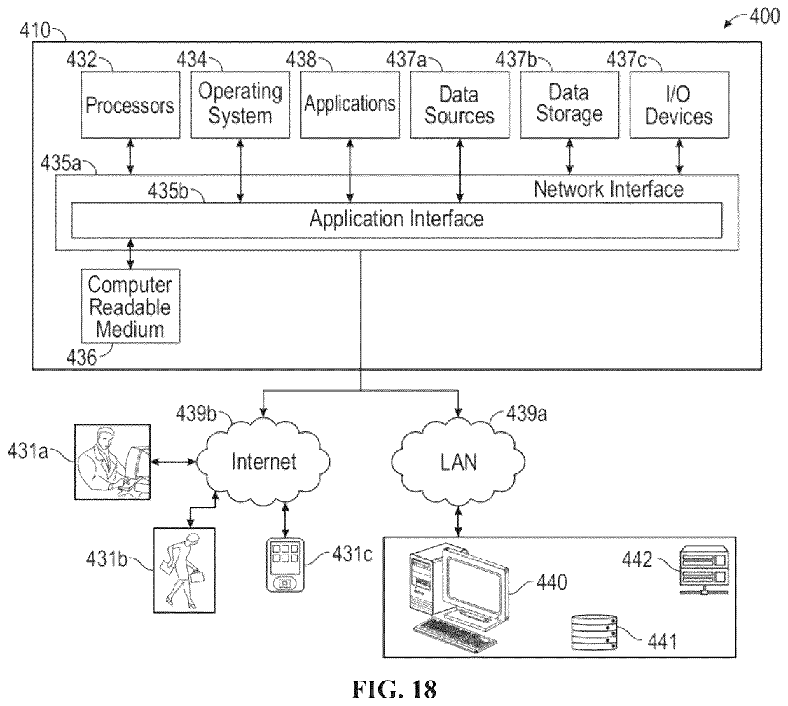

FIG. 18 illustrates a computer system 410 enabling or comprising the systems and methods in accordance with some embodiments of the system. In some embodiments, the computer system 410 can operate and/or process computer-executable code of one or more software modules of the aforementioned system and method. Further, in some embodiments, the computer system 410 can operate and/or display information within one or more graphical user interfaces (e.g., HMIs) integrated with or coupled to the system.

In some embodiments, the computer system 410 comprises at least one processor 432. In some embodiments, the at least one processor 432 can reside in, or coupled to, one or more conventional server platforms (not shown). In some embodiments, the computer system 410 can include a network interface 435a and an application interface 435b coupled to the least one processor 432 capable of processing at least one operating system 434. Further, in some embodiments, the interfaces 435a, 435b coupled to at least one processor 432 can be configured to process one or more of the software modules (e.g., such as enterprise applications 438). In some embodiments, the software application modules 438 can include server-based software, and can operate to host at least one user account and/or at least one client account, and operate to transfer data between one or more of these accounts using the at least one processor 432.

With the above embodiments in mind, it is understood that the system can employ various computer-implemented operations involving data stored in computer systems. Moreover, the above-described databases and models described throughout this disclosure can store analytical models and other data on computer-readable storage media within the computer system 410 and on computer-readable storage media coupled to the computer system 410 according to various embodiments. In addition, in some embodiments, the above-described applications of the system can be stored on computer-readable storage media within the computer system 410 and on computer-readable storage media coupled to the computer system 410. In some embodiments, these operations are those requiring physical manipulation of physical quantities. Usually, though not necessarily, in some embodiments these quantities take the form of one or more of electrical, electromagnetic, magnetic, optical, or magneto-optical signals capable of being stored, transferred, combined, compared and otherwise manipulated. In some embodiments, the computer system 410 can comprise at least one computer readable medium 436 coupled to at least one of at least one data source 437a, at least one data storage 437b, and/or at least one input/output 437c. In some embodiments, the computer system 410 can be embodied as computer readable code on a computer readable medium 436. In some embodiments, the computer readable medium 436 can be any data storage that can store data, which can thereafter be read by a computer (such as computer 440). In some embodiments, the computer readable medium 436 can be any physical or material medium that can be used to tangibly store the desired information or data or instructions and which can be accessed by a computer 440 or processor 432. In some embodiments, the computer readable medium 436 can include hard drives, network attached storage (NAS), read-only memory, random-access memory, FLASH based memory, CD-ROMs, CD-Rs, CD-RWs, DVDs, magnetic tapes, other optical and non-optical data storage. In some embodiments, various other forms of computer-readable media 436 can transmit or carry instructions to a remote computer 440 and/or at least one user 431, including a router, private or public network, or other transmission or channel, both wired and wireless. In some embodiments, the software application modules 438 can be configured to send and receive data from a database (e.g., from a computer readable medium 436 including data sources 437a and data storage 437b that can comprise a database), and data can be received by the software application modules 438 from at least one other source. In some embodiments, at least one of the software application modules 438 can be configured within the computer system 410 to output data to at least one user 431 via at least one graphical user interface rendered on at least one digital display.

In some embodiments, the computer readable medium 436 can be distributed over a conventional computer network via the network interface 435a where the system embodied by the computer readable code can be stored and executed in a distributed fashion. For example, in some embodiments, one or more components of the computer system 410 can be coupled to send and/or receive data through a local area network (“LAN”) 439a and/or an internet coupled network 439b (e.g., such as a wireless internet). In some embodiments, the networks 439a, 439b can include wide area networks (“WAN”), direct connections (e.g., through a universal serial bus port), or other forms of computer-readable media 436, or any combination thereof.

In some embodiments, components of the networks 439a, 439b can include any number of personal computers 440 which include for example desktop computers, and/or laptop computers, or any fixed, generally non-mobile internet appliances coupled through the LAN 439a. For example, some embodiments include one or more of personal computers 440, databases 441, and/or servers 442 coupled through the LAN 439a that can be configured for any type of user including an administrator. Some embodiments can include one or more personal computers 440 coupled through network 439b. In some embodiments, one or more components of the computer system 410 can be coupled to send or receive data through an internet network (e.g., such as network 439b). For example, some embodiments include at least one user 431a, 431b, is coupled wirelessly and accessing one or more software modules of the system including at least one enterprise application 438 via an input and output (“I/O”) 437c. In some embodiments, the computer system 410 can enable at least one user 431a, 431b, to be coupled to access enterprise applications 438 via an I/O 437c through LAN 439a. In some embodiments, the user 431 can comprise a user 43 la coupled to the computer system 410 using a desktop computer, and/or laptop computers, or any fixed, generally non-mobile internet appliances coupled through the internet 439b. In some embodiments, the user can comprise a mobile user 431b coupled to the computer system 410. In some embodiments, the user 431b can connect using any mobile computing 431c to wireless coupled to the computer system 410, including, but not limited to, one or more personal digital assistants, at least one cellular phone, at least one mobile phone, at least one smart phone, at least one pager, at least one digital tablets, and/or at least one fixed or mobile internet appliances.

The subject matter described herein are directed to technological improvements to the field of electrical usage metering by providing commercial grade DC meters that can be used in conjunction with AC meters, where the DC and AC meters also provide power source control. The disclosure also describes the specifics of how a machine including one or more computers comprising one or more processors and one or more non-transitory computer implement the system and its improvements over the prior art. The instructions executed by the machine cannot be performed in the human mind or derived by a human using a pin and paper but require the machine to convert process input data to useful output data. Moreover, the claims presented herein do not attempt to tie-up a judicial exception with known conventional steps implemented by a general-purpose computer; nor do they attempt to tie-up a judicial exception by simply linking it to a technological field. Indeed, the systems and methods described herein were unknown and/or not present in the public domain at the time of filing, and they provide a technologic improvements advantages not known in the prior art. Furthermore, the system includes unconventional steps that confine the claim to a useful application.

It is understood that the system is not limited in its application to the details of construction and the arrangement of components set forth in the previous description or illustrated in the drawings. The system and methods disclosed herein fall within the scope of numerous embodiments. The previous discussion is presented to enable a person skilled in the art to make and use embodiments of the system. Any portion of the structures and/or principles included in some embodiments can be applied to any and/or all embodiments: it is understood that features from some embodiments presented herein are combinable with other features according to some other embodiments. Thus, some embodiments of the system are not intended to be limited to what is illustrated but are to be accorded the widest scope consistent with all principles and features disclosed herein.

Some embodiments of the system are presented with specific values and/or setpoints. These values and setpoints are not intended to be limiting and are merely examples of a higher configuration versus a lower configuration and are intended as an aid for those of ordinary skill to make and use the system.

Furthermore, acting as Applicant's own lexicographer, Applicant imparts the additional meaning to the following terms:

“Substantially” and “approximately” when used in conjunction with a value encompass a difference of 5% or less of the same unit and/or scale of that being measured. In some embodiments, “substantially” and “approximately” are defined as presented in the specification in accordance with some embodiments.

“Simultaneously” as used herein includes lag and/or latency times associated with a conventional and/or proprietary computer, such as processors and/or networks described herein attempting to process multiple types of data at the same time. “Simultaneously” also includes the time it takes for digital signals to transfer from one physical location to another, be it over a wireless and/or wired network, and/or within processor circuitry.

The use of and/or, in terms of “A and/or B,” means one option could be “A and B” and another option could be “A or B.” Such an interpretation is consistent with the USPTO Patent Trial and Appeals Board ruling in ex parte Gross, where the Board established that “and/or” means clement A alone, clement B alone, or elements A and B together.

As used herein, some embodiments recited with term “can” or “may” or derivations there of (e.g., the system display can show X) is for descriptive purposes only and is understood to be synonymous with “configured to” (e.g., the system display is configured to show X) for defining the metes and bounds of the system

The previous detailed description is to be read with reference to the figures, in which like elements in different figures have like reference numerals. The figures, which are not necessarily to scale, depict some embodiments and are not intended to limit the scope of embodiments of the system.

Any of the operations described herein that form part of the invention are useful machine operations. The invention also relates to a device or an apparatus for performing these operations. The apparatus can be specially constructed for the required purpose, such as a special purpose computer. When defined as a special purpose computer, the computer can also perform other processing, program execution or routines that are not part of the special purpose, while still being capable of operating for the special purpose. Alternatively, the operations can be processed by a general-purpose computer selectively activated or configured by one or more computer programs stored in the computer memory, cache, or obtained over a network. When data is obtained over a network the data can be processed by other computers on the network, e.g. a cloud of computing resources.

The embodiments of the invention can also be defined as a machine that transforms data from one state to another state. The data can represent an article, that can be represented as an electronic signal and electronically manipulate data. The transformed data can, in some cases, be visually depicted on a display, representing the physical object that results from the transformation of data. The transformed data can be saved to storage generally, or in particular formats that enable the construction or depiction of a physical and tangible object. In some embodiments, the manipulation can be performed by a processor. In such an example, the processor thus transforms the data from one thing to another. Still further, some embodiments include methods can be processed by one or more machines or processors that can be connected over a network. Each machine can transform data from one state or thing to another, and can also process data, save data to storage, transmit data over a network, display the result, or communicate the result to another machine. Computer-readable storage media, as used herein, refers to physical or tangible storage (as opposed to signals) and includes without limitation volatile and non-volatile, removable and non-removable storage media implemented in any method or technology for the tangible storage of information such as computer-readable instructions, data structures, program modules or other data.

Although method operations are presented in a specific order according to some embodiments, the execution of those steps do not necessarily occur in the order listed unless a explicitly specified. Also, other housekeeping operations can be performed in between operations, operations can be adjusted so that they occur at slightly different times, and/or operations can be distributed in a system which allows the occurrence of the processing operations at various intervals associated with the processing, as long as the processing of the overlay operations are performed in the desired way and result in the desired system output.

It will be appreciated by those skilled in the art that while the invention has been described above in connection with particular embodiments and examples, the invention is not necessarily so limited, and that numerous other embodiments, examples, uses, modifications and departures from the embodiments, examples and uses are intended to be encompassed by the claims attached hereto. The entire disclosure of each patent and publication cited herein is incorporated by reference, as if each such patent or publication were individually incorporated by reference herein.

We claim:

1. A direct current (DC) metering system comprising:
a DC meter;
wherein the DC meter is configured to be integrated into an electrical transmission line;
wherein the DC meter is configured to measure and/or record a transfer of electricity from a DC power source to an electrical load along the electrical transmission line; and
wherein the DC meter is configured to receive and/or control an electrical input from two or more DC power sources.

2. The DC metering system of claim 1,
wherein the DC meter comprises multiple parallel generation circuitry; and
wherein the multiple parallel generation circuitry enables the DC metering to draw power from the two or more DC power sources simultaneously.

3. The DC metering system of claim 1,
wherein the DC meter comprises a controller that enables a user to control one or more DC meter functions; and
wherein the one or more DC meter functions include one or more of: selecting which of the two or more DC power sources to enable automatically, selecting a sequence for bringing the two or more DC power sources online, and configuring the DC meter to transmit electricity from each of the two or more DC power sources in parallel.

4. The DC metering system of claim 1,
wherein the DC meter includes two or more DC inputs;
wherein the DC meter includes one or more DC outputs; and
wherein the DC meter is configured to transmit electricity from each of the two or more DC inputs to the one or more DC outputs.

5. The DC metering system of claim 4,
wherein the DC meter includes two or more channels; and
wherein the two or more channels each comprise an electricity transmission connection between at least one of the two or more DC inputs and at least one of the one or more DC outputs.

6. The DC metering system of claim 5,
wherein the DC meter is configured to measure and record an amount of electricity flowing through each of the two or more channels.

7. The DC metering system of claim 3,
wherein the DC meter includes at least a first DC input and a second DC input each configured to receive the electricity from a first DC power source and a second DC power source, respectively; and
wherein the DC meter includes at least a first DC output and a second DC output each configured to send the electricity to a first electrical load and a second electrical load, respectively.

8. The DC metering system of claim 7,
wherein the controller is configured to enable a user to select to send electricity from the first DC power source or second DC power source to one or more of the first electrical load, the second electrical load, and both the first electrical load and the second electrical load.

9. The DC metering system of claim 8,
wherein the controller is configured to enable a user to combine electricity from the first DC power source with electricity from the second DC power source before sending the combined electricity to one or more of the first electrical load, the second electrical load, and both the first electrical load and the second electrical load.

10. The DC metering system of claim 7,
wherein the DC meter is configured to measure, record, and/or transmit an amount of electricity flowing through each of the first DC input, the second DC input, the first DC output, and second DC output.

11. The DC metering system of claim 7,
wherein the DC meter comprises a housing comprising a user interface configured to enable a user to visually and/or audibly receive information from the DC meter and/or control one or more DC meter functions.
